(19) United States
(12) Patent Application Publication
(10) Pub. No.: US 2011/0095832 A1
(43) Pub. Date: Apr. 28, 2011

(54) Fast start, low power oscillator system

(76) Inventor: Orest Fedan, Belmont, MA (US)

(21) Appl. No.: 12/589,366

(22) Filed: Oct. 22, 2009

(51) Int. Cl. H03B 5/02

(52) U.S. Cl. 331/108 R

(57) ABSTRACT

A fast start, low power oscillator system includes an oscillator circuit including an amplifier and a tank circuit, the amplifier including an operating resistance which sets the amplifier operating current and a speed-up circuit including a switching circuit for temporarily increasing the operating current to an elevated level at start-up and then returning it to the original operating current when the oscillator reaches its operating amplitude.

### FIELD OF THE INVENTION

This invention relates to a fast start, low power oscillator system having low current consumption and a wide, linear pull range.

### BACKGROUND OF THE INVENTION

In a typical voltage controlled crystal oscillator (VCXO) a voltage controlled capacitance pulls the oscillation frequency and one or more resistors determine the operating current. Additional capacitances set up the negative resistance condition for oscillation and also help to isolate the transistor from the crystal resonator thus reducing its effect on the stability of the oscillator over temperature. Where bipolar transistors are used, the resistance in the emitter circuit is the dominant determiner of operating current and also affects the frequency range and linearity of frequency pulling by the voltage controlled capacitance. It is desirable for such oscillators to have a large, linear pull range, low current, low power consumption and fast start up: typical start-up times are in the 15-20 millisecond range. Unfortunately, however, if the oscillator is based at a lower operating current the start-up time is longer, and if it is based at higher operating current, it may start quicker but the pull range will be reduced and will be less linear.

### SUMMARY OF THE INVENTION

In accordance with various aspects of the subject invention in at least one embodiment the invention presents an improved fast start, low power oscillator system which has a larger, more linear, frequency pull range, lower current and power operation and faster start-up.

The subject invention results from the realization, that an improved fast start, power oscillator system having a larger, more linear frequency pull range, lower current and power operation and faster start-up can be achieved using an oscillator circuit having an amplifier and a tank circuit, the amplifier including an operating resistance which sets the operating current and a speed-up circuit including a switching circuit for temporarily increasing the operating current to an elevated level at start-up and then returning it to the original operating current when the oscillator reaches it operating amplitude.

The subject invention, however, in other embodiments, need not achieve all these objectives and the claims hereof should not be limited to structures or methods capable of achieving these objectives.

This invention features a fast start, low power oscillator system including an oscillator circuit including an amplifier and a tank circuit, the amplifier including an operating resistance which sets the amplifier operating current and a speed-up circuit including a switching circuit for temporarily increasing the operating current to an elevated level at start-up and then returning it to the original operating current when the oscillator reaches its operating amplitude.

In a preferred embodiment the oscillator circuit may be a Colpitts oscillator or a Pierce oscillator or a Clapp oscillator. The amplifier may include a bipolar transistor and the Colpitts oscillator may be a common collector oscillator. The amplifier may include a bipolar transistor and the Pierce oscillator may be a common emitter oscillator. The amplifier may include a bipolar transistor and the Clapp oscillator may be a common base oscillator. The switching circuit may apply a resistance in parallel with the operating resistance to increase the operating current during start-up. The switching circuit may shunt a portion of the operating resistance to increase operating current during start-up.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a schematic diagram of a prior art Colpitts VCXO;

FIG. 2 is a schematic diagram of an improved voltage controlled crystal oscillator system according to this invention;

FIG. 3 is a more generalized view of the invention implementable as any type of oscillator, e.g. Colpitts, Pierce, Clapp;

FIG. 4 is a view similar to FIG. 3 disclosing another approach to temporarily boosting the start-up current; and

FIG. 5 is an illustration of the improved performance of the oscillator system according to this invention.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

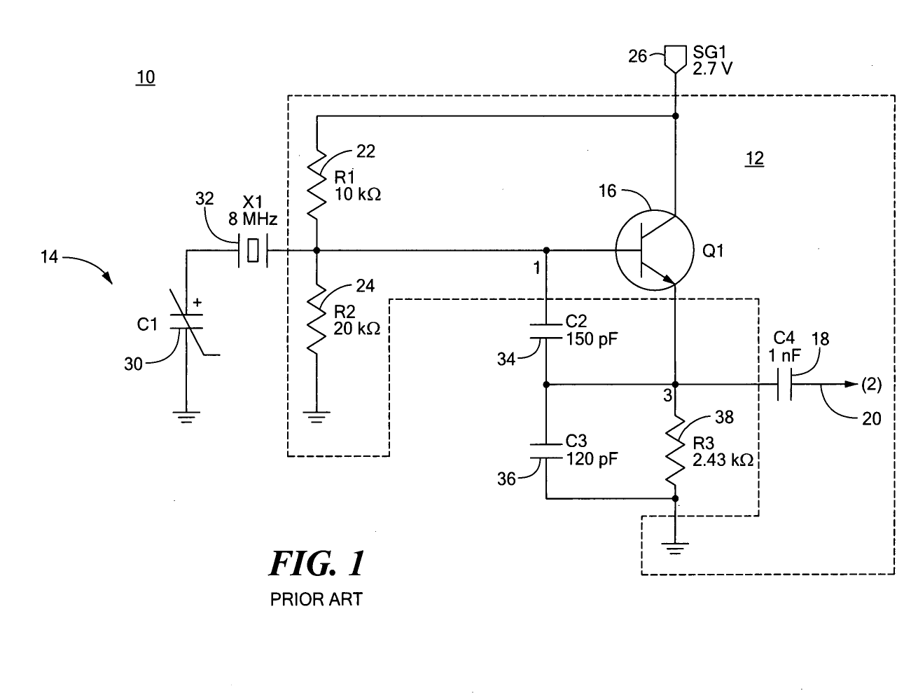

There is shown in FIG. 1 a conventional prior art voltage controlled crystal oscillator 10 (VCXO) configured as a Colpitts oscillator using a bi-polar transistor connected as an ac grounded collector. Oscillator 10 includes an amplifier 12 and tank circuit 14. Amplifier 12 includes bi-polar transistor 16, coupling capacitor 18 which provides the output on line 20 and voltage divider resistors 22 and 24. Input power is provided at terminal 26. Tank circuit 14 includes voltage control capacitor 30, crystal resonator 32, negative resistance feedback capacitors 34 and 36 and emitter resistance 38. Emitter resistance may also be considered as a part of amplifier circuit 12.

In operation, resistances 22 and 24 set the average base voltage on transistor 16 around which the alternating current varies. Any perturbation starts current flowing either in the positive direction from voltage controlled capacitance 30 through capacitance 34 and then capacitance 36 or in the opposite, negative, direction from capacitance 36 through capacitor 34 and then through capacitor 30. Assuming a positive flow from capacitor 30 through 34 through 36, capacitor 34 charges turning on transistor 16 harder; more current flows from the collector through the emitter. The emitter current flows mostly through capacitance 36 and some through resistance 38. As the cycle reverses capacitance 36 is now at a higher voltage so a stronger reverse current is generated. Capacitance 34 thus discharges to a lower voltage because reverse current is stronger than it would have been and so it turns transistor 16 off harder. This drops the voltage on capacitance 36 and so capacitance 36 loses more charge than it would have if transistor 16 wasn't turned off so hard. And the cycle continues in this manner.

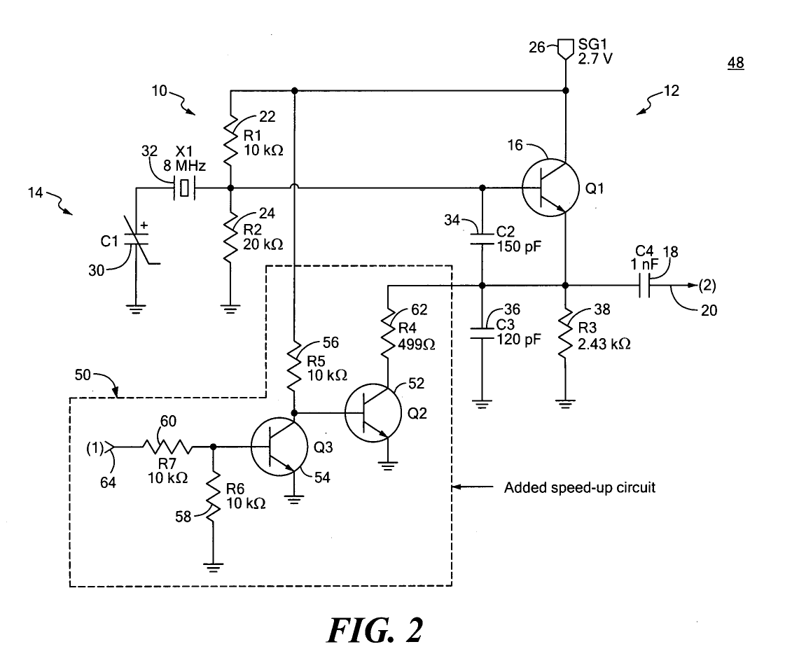

The fast start, low power oscillator system 48, FIG. 2, according to this inventor includes all of the parts of oscillator circuit 10, FIG. 1, but in addition adds speed-up circuit 50, which includes a switching circuit having transistors 52 and 54, biasing resistances 56, 58, 60, operating current control resistance 62 and an input terminal 64.

In operation, when power is first applied the voltage at input terminal 64 is kept low, thus keeping transistor 54 off and transistor 52 on. In this state resistance 62 parallels resistance 38 increasing the operating current through transistor 16 and the operating current of the oscillator. Once again in oscillator 10 resistances 22 and 24 set the average base voltage on transistor 16 around which the alternating current varies. Any perturbation starts the current flowing either in a direction from capacitor 30 to 34 to 36 or in the reverse direction from capacitor 36 to 34 to 30. The oscillation amplitude builds with each cycle. After oscillation reaches full amplitude, a voltage of 2.0 volts or higher is applied to terminal (1) 64. This turns on transistor 54 consequently turning off transistor 52 and removing resistance 62 from the oscillation circuit by opening circuiting it. The operating current of the oscillator is now much lower than its original operating current value and is mostly controlled by resistance 38. The values actually shown in FIG. 2 provide a 5 to 1 reduction in operating current when a voltage is applied to terminal 64. This is close to the ideal amount, preserving the best balance between a wide and linear pull range and a fast start-up. It is good to keep resistance 62 and transistor 52 physically close to the rest of the oscillator circuit to minimize the effect of parasitic printed circuit board capacitance on the oscillation frequency. To the same end transistor 52 should have a very low output capacitance when it is in the off condition.

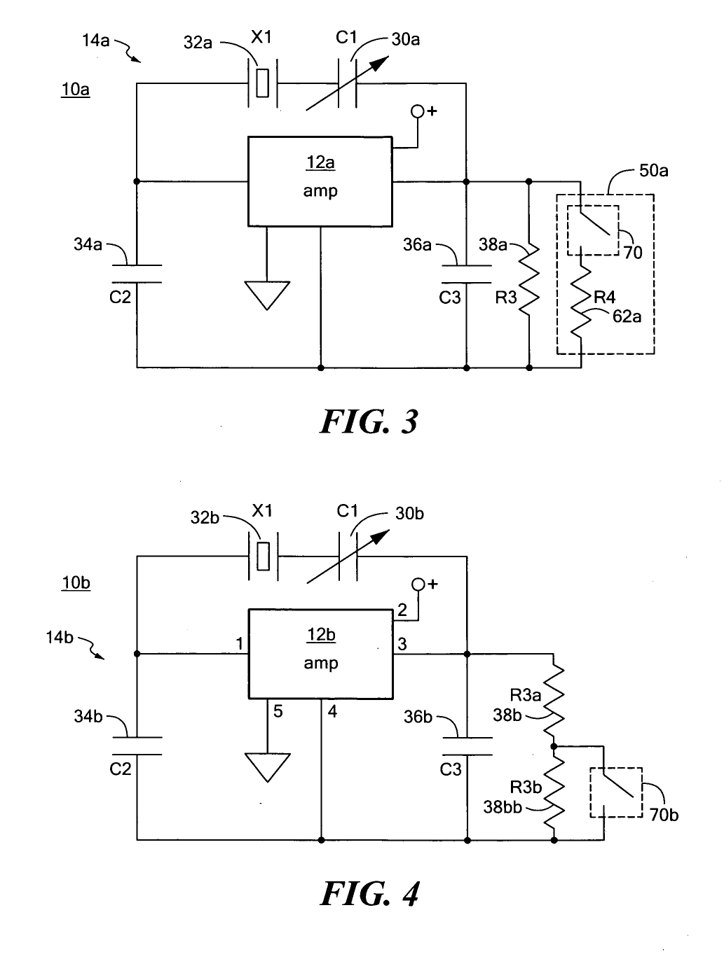

Although thus far the embodiment shown uses a Colpitts oscillator implemented with a bipolar transistor neither of these are limitations of the invention. For example, as shown in FIG. 3, a more generalized illustration of the oscillator system 48, according to this invention employs an amplifier 12a and tank circuit 14a which uses switch circuit 50a. The oscillator circuit may be a Colpitts, or a Pierce or a Clapp, for example and if a Colpitts is used with a bipolar transistor it takes the form of a common collector circuit. If a Pierce oscillator circuit is used with a bipolar transistor then it takes the form of a common emitter circuit and if a Clapp oscillator is implemented using a bipolar transistor it takes the form of a common base circuit. In FIG. 3 for ease of representation switch 70 actually represents speed-up circuit 50 including as shown in FIG. 2 resistances 56, 58, 60 input terminal 64 and transistors 52 and 54.

Although thus far the specific and more general implementations of the invention shown use the speed up circuit to switch a resistance in parallel with emitter resistance 38 or 38a during start up to temporally increase the current and then remove resistance 62 or 62a from the circuit to return the current to its original operating value, this is not a limitation of the invention. For example, as shown in FIG. 4, operating resistance 38, FIG. 2, or 38a, FIG. 3, may be split up into two resistances 38b and 38bb with 38bb being paralleled by switching circuit 70b. In that case resistance 38b could be formed at 499 ohms, for example, and resistance 38bb could be 2,000 ohms. At start-up switch 70b would be closed to shunt 2,000 ohm resistance 38bb and provide a much higher operating current through resistance 38b alone. After start-up switch 70b may be opened to reintroduce the 2,000 ohm higher resistance 38bb in series with resistance 38b to reduce the operating current to its normal value.

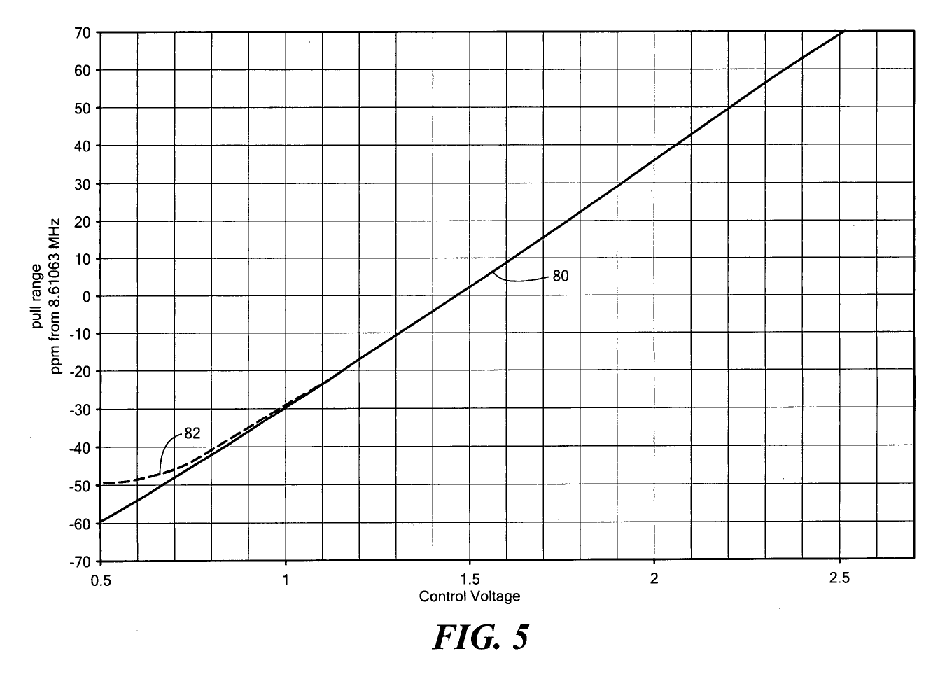

Some of the improvement achieved by this invention is represented in FIG. 5, which shows a characteristic of control voltage versus pull range indicated by characteristic 80. Also shown is the path of the characteristic 80 at a higher operating current 82 such as would be the case if the increased current were maintained throughout all operation, not just at start-up. If the start-up current level was kept high all the time it would reduce the pull range by approximately 10 ppm which is a significant improvement. And even with this improvement in pull range the start-up time with this invention can be reduced to as low as 2 milliseconds from a typical start-up time of 15 to 20 milliseconds.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. A fast start, low power oscillator system comprising:
an oscillator circuit including an amplifier and a tank circuit, said amplifier including an operating resistance which sets the amplifier operating current; and
a speed-up circuit including a switching circuit for temporarily increasing the operating current to an elevated level at start-up and then returning it to the original operating current when the oscillator reaches its operating amplitude.

2. The oscillator system of claim 1 in which said oscillator circuit is a Colpitts oscillator.

3. The oscillator system of claim 1 in which said oscillator circuit is a Pierce oscillator.

4. The oscillator system of claim 1 in which said oscillator circuit is a Clapp oscillator.

5. The oscillator system of claim 2 in which said amplifier includes a bipolar transistor and the Colpitts oscillator is a common collector oscillator.

6. The oscillator system of claim 3 in which said amplifier includes a bipolar transistor and the Pierce oscillator is a common emitter oscillator.

7. The oscillator system of claim 4 in which said amplifier includes a bipolar transistor and the Clapp oscillator is a common base oscillator.

8. The oscillator system of claim 1 in which said switching circuit applies a resistance in parallel with said operating resistance to increase the operating current during start-up.

9. The oscillator system of claim 1 in which said switching circuit shunts a portion of said operating resistance to increase operating current during start-up.
